(19) United States
(12) Patent Application Publication
(10) Pub. No.: US 2024/0281586 A1
(43) Pub. Date: Aug. 22, 2024

(54) CIRCUIT LAYOUT METHOD AND DEVICE

(71) Applicant: ASUSTeK COMPUTER INC., Taipei City (TW)

(72) Inventor: Tai-Lang Chang, Taipei City (TW)

(73) Assignee: ASUSTeK COMPUTER INC., Taipei City (TW)

(21) Appl. No.: 18/300,334

(22) Filed: Apr. 13, 2023

(30) Foreign Application Priority Data
Feb. 17, 2023 (TW) 112105781

(51) Int. Cl. G06F 30/392; G06F 30/347

(52) U.S. Cl. CPC G06F 30/392; G06F 30/347

(57) ABSTRACT

A circuit layout method and a circuit layout device. The method is adapted for a circuit layout of a common board circuit between a CPU, a GPU and a multimedia interface connector. The common board circuit includes a design circuit and a signal conditioner. The method includes the following steps: a common board evaluation is performed on multiple predetermined models according to a first layout design specification of the CPU and a second layout design specification of the GPU; the design circuit is planned according to a result of the common board evaluation; the suitable signal conditioner is selected according to the planned design circuit; and the first layout design specification, the second layout design specification and a third layout design specification of the signal conditioner are integrated, and accordingly a layout circuit diagram of the common board circuit is drawn.

### CROSS-REFERENCE TO RELATED APPLICATION

This application claims the priority benefit of Taiwan application serial no. 112105781, filed on Feb. 17, 2023. The entirety of the above-mentioned patent application is hereby incorporated by reference herein and made a part of this specification.

### BACKGROUND

### Technical Field

The disclosure relates to a circuit layout method and device for high-speed signals of a high definition multimedia interface (HDMI).

### Description of Related Art

A high definition multimedia interface (HDMI) is a fully digitized image and sound transmission interface, which may simultaneously transmit high-quality audio signals and video signals, and is also the most common multimedia interface in today's computer devices. High-speed signals used by the HDMI may come from a central processing unit (CPU) or a graphics processing unit (GPU) according to different models of the computer devices. In the case of using a common board design (a common printed circuit board (PCB) design) for the different models, if a same HDMI connector is used to output the high-speed signals at the same time, it is necessary to use a multiplexer to perform signal port switching, which leads to problems of insufficient space on the printed circuit board and increased cost.

### SUMMARY

The disclosure provides a circuit layout method adapted to a circuit layout of a common board circuit between a central processing unit (CPU), a graphics processing unit (GPU) and a multimedia interface connector. The common board circuit includes a design circuit and a signal conditioner. The method includes following steps: performing a common board evaluation on multiple predetermined models according to a first layout design specification of the CPU and a second layout design specification of the GPU; planning the design circuit according to a result of the common board evaluation; selecting the suitable signal conditioner according to the planned design circuit; and integrating the first layout design specification, the second layout design specification and a third layout design specification of the signal conditioner, and accordingly drawing a layout circuit diagram of the common board circuit.

The disclosure further provides a circuit layout device, which performs a circuit layout of a common board circuit between a CPU, a GPU and a multimedia interface connector. The common board circuit includes a design circuit and a signal conditioner. The circuit layout device includes a storage device and a circuit layout processor. The storage device is configured to store a design rule sorting and a circuit and layout design route evaluation plan. The circuit layout processor is coupled to the storage device, and is configured to load the design rule sorting and the circuit and layout design route evaluation plan to execute: performing a common board evaluation on multiple predetermined models according to a first layout design specification of the CPU and a second layout design specification of the GPU; planning the design circuit according to a result of the common board evaluation; selecting the suitable signal conditioner according to the planned design circuit; and integrating the first layout design specification, the second layout design specification and a third layout design specification of the signal conditioner, and accordingly drawing a layout circuit diagram of the common board circuit.

Based on the above description, the circuit layout method and device in the disclosure simultaneously consider the layout design specifications of the CPU and the GPU, and select the suitable signal conditioner for matching, so as to draw the layout circuit diagram that conforms to the common board design. In this way, the multiplexer on the existing design may be replaced, thereby increasing an available space on the circuit board and reducing the cost.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a block diagram of a circuit layout device according to an embodiment of the disclosure.

FIG. 2 is a block diagram illustrating sorting and plan of circuit layout rules according to an embodiment of the disclosure.

FIG. 3 is a circuit structure diagram of high-speed signals on a printed circuit board according to an embodiment of the disclosure.

FIG. 4 is a flowchart of a circuit layout method according to an embodiment of the disclosure.

FIG. 5 is a flowchart of a circuit layout method according to an embodiment of the disclosure.

### DESCRIPTION OF THE EMBODIMENTS

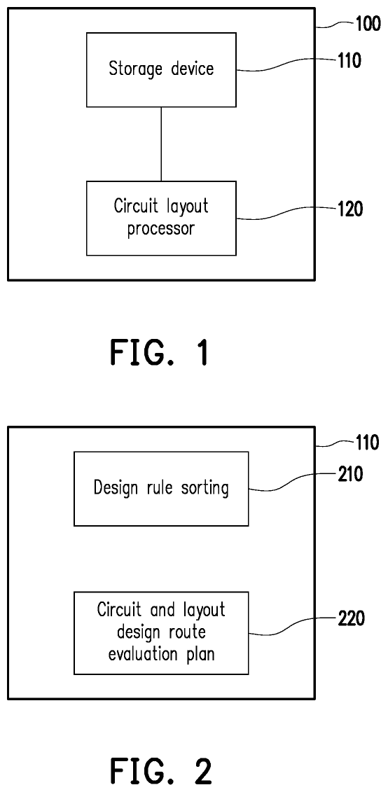

Referring to FIG. 1, a circuit layout device 100 of the embodiment is, for example, an electronic device such as a personal computer, a smart phone, a personal digital assistant (PDA), a notebook computer, a tablet computer or a server, etc., and includes a storage device 110 and a circuit layout processor 120.

The storage device 110 is, for example, any type of a fixed or removable random access memory (RAM), a read-only memory (ROM), a flash memory, a hard disk or a similar component or a combination of the above components, and is for storing computer programs executable by the circuit layout processor 120 and data used by the same.

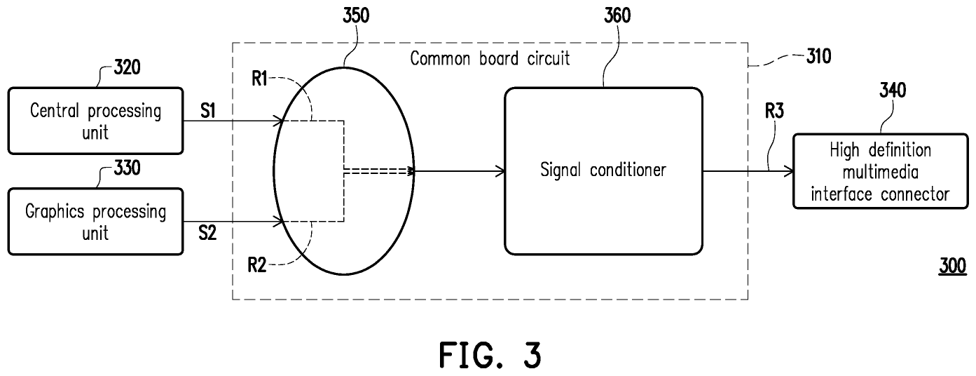

In detail, referring to FIG. 2, the storage device 110 stores related data of circuit layout rules, which includes a design rule sorting 210 and a circuit and layout design route evaluation plan 220. The design rule sorting 210 includes processor high-speed signal selection and specification confirmation, high-speed signal line design guide and rule sorting, and definition of common board design specification. The circuit and layout design route evaluation plan 220 includes a PCB high-speed signal channel level plan and electronic component position configuration and placement, which must comply with specifications of common board design guide.

The circuit layout processor 120 is coupled to the storage device 110. The circuit layout processor 120 is, for example, a central processing unit (CPU), or other programmable general purpose or special purpose microprocessor, digital signal processor (DSP), programmable controller, application specific integrated circuit (ASIC) or other similar components or a combination of the above components. In the embodiment, the circuit layout processor 120 may load the design rule sorting 210 and the circuit and layout design route evaluation plan 220 from the storage device 110 to execute the circuit layout method of the embodiment of the disclosure.

The circuit layout method of the embodiment of the disclosure is suitable for performing circuit layout on a common board circuit between a CPU, a GPU and a multimedia interface connector on a printed circuit board. As shown in FIG. 3, on a printed circuit board 300, a common board circuit 310 of the embodiment refers to a circuit coupled between a CPU 320, a GPU 330 and a HDMI connector 340. The common board circuit 310 includes a design circuit 350 and a signal conditioner 360. The design circuit 350 at least includes a first route R1 and a second route R2. Where, the first route R1 is coupled between the CPU 320 and the signal conditioner 360, and the second route R2 is coupled between the GPU 330 and the signal conditioner 360. The following embodiments are provided to illustrate detailed steps of the circuit layout method of the disclosure. In the embodiment, the CPU 320 may provide a high-speed signal S1 supporting a HDMI 2.0 certification specification, and the GPU 330 may provide the high-speed signal S2 supporting a HDMI 2.1 certification specification, but the disclosure is not limited thereto.

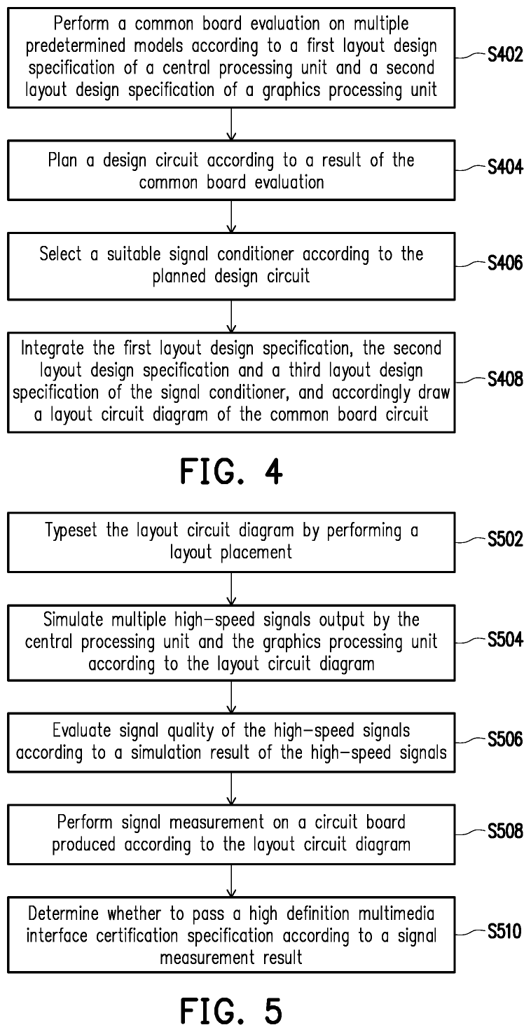

Referring to FIG. 2, FIG. 3 and FIG. 4 at the same time, the circuit layout method of the embodiment may be applicable to the circuit layout device 100 of FIG. 1, and steps thereof are described as follows:

First, in step S402, the circuit layout processor 120 performs a common board evaluation on multiple predetermined models according to a first layout design specification of the CPU 320 and a second layout design specification of the GPU 330. The predetermined models at least include a model including only a CPU and a model having both of the CPU and a GPU. To be specific, the circuit layout processor 120 may determine whether the design circuit 350 common to multiple predetermined models may be planned according to the first layout design specification and the second layout design specification. The first layout design specification is, for example, a design guide published by a manufacturer of the CPU 320 for circuit design, and the second layout design specification is, for example, a design guide published by a manufacturer of the GPU 330 for circuit design. Items specified in the first layout design specification and the second layout design specification (such as specified line length, impedance control, etc.) are pre-stored in the storage device 110. In this way, the circuit layout processor 120 may comprehensively consider the items specified in the first layout design specification and the second layout design specification, and integrate a feasible circuit design scheme that complies with the first layout design specification and the second layout design specification at the same time, and accordingly determine whether the design circuit 350 common to multiple predetermined models may be planned on the printed circuit board 300.

Then, in step S404, the circuit layout processor 120 plans the design circuit 350 according to a result of the common board evaluation. Specifically, if the feasible circuit design scheme is obtained after the common board evaluation, the circuit layout processor 120 may plan the design circuit 350 accordingly. On the other hand, if no feasible circuit design scheme is obtained after the common board evaluation, the circuit layout processor 120 may sort out and list reasons of the infeasibility to serve as a subsequent reference.

Then, in step S406, the circuit layout processor 120 selects the applicable signal conditioner 360 according to the planned design circuit 350. In the embodiment, the signal conditioner 360 may be, for example, a signal amplifier or a signal re-timer. For example, specification data of multiple signal conditioners (such as chips of Parade PS8419, Diodes PI3HDX12211, etc.) that may support the HDMI 2.1 certification specification may be pre-stored in the storage device 110. The circuit layout processor 120 selects a suitable signal conditioner from multiple signal conditioners stored in the storage device 110 according to the planned design circuit 350 to serve as the signal conditioner 360.

Finally, in step S408, the circuit layout processor 120 integrates the first layout design specification, the second layout design specification, and a third layout design specification of the signal conditioner 360, and accordingly draws a layout circuit diagram of the common board circuit 310. For example, the third layout design specification is, for example, a design guide published by a manufacturer of the signal conditioner 360 for circuit design, and the specified items (such as specified line length, impedance control, etc.) are pre-stored in the storage device 110. The circuit layout processor 120 may first, for example, sort and list specification data such as a pre-channel length, impedance controlled, a post channel length, a pre-channel inter pair length, a post channel inter pair length, an intra pair length, etc., specified by the first layout design specification, the second layout design specification, and the third layout design specification, and then propose an integrated design specification that may meet each layout design specification at the same time. Moreover, the circuit layout processor 120 may draw a layout circuit diagram of the common board circuit 310 according to the integrated design specification.

In an embodiment, after the above-mentioned circuit layout method, the drawn layout circuit diagram is typeset and optimized, and simulation of the high-speed signals S1 and S2 and measurement of actual signals are performed.

In detail, referring to FIG. 2, FIG. 3 and FIG. 5, the flow of the circuit layout method of the embodiment may be carried out after step S408 of the aforementioned embodiment, and this method is also applicable to the circuit layout device 100 in FIG. 1, and the steps are described as follows:

First, in step S502, the circuit layout processor 120 typesets the layout circuit diagram by performing layout placement. To be specific, the circuit layout processor 120 may perform layout placement in collaboration with a bill of materials (BOM), so as to typeset and optimize the drawn layout circuit diagram.

Then, in step S504, the circuit layout processor 120 simulates the high-speed signals S1 and S2 (such as Diff TX signals) output by the CPU 320 and the GPU 330 according to the layout circuit diagram. To be specific, the circuit layout processor 120 may simulate the high-speed signal on the first route R1 (coupled between the CPU 320 and the signal conditioner 360) in the design circuit 350, the high-speed signal on the second route R2 (coupled between the GPU 320 and the signal conditioner 360) in the design circuit 350 and the high-speed signal on the third route R3 coupled between the signal conditioner 360 and the HDMI connector 340, and generate a corresponding signal eye pattern.

Then, in step S506, the circuit layout processor 120 evaluates signal quality of the high-speed signals S1 and S2 according to simulation results of the high-speed signals S1 and S2. To be specific, the circuit layout processor 120 may evaluate the signal quality of the high-speed signals S1 and S2 according to whether an area of an eye-height-eye-width part (a blank part in the middle) of each signal eye pattern is larger than a specified standard area. In the embodiment, the high-speed signal on the first route R1 is evaluated by using the specified standard conforming to the HDMI 2.0 certification specification, and the high-speed signals on the second route R2 and the third route R3 are evaluated by using the specified standard conforming to the HDMI 2.1 certification specification, but the disclosure is not limited thereto. If an area of an eye-shaped part is much larger than the specified standard area, it means that the signal quality is good, the layout is correct, and the margin is large enough, so that it is evaluated as high feasibility.

Then, in step S508, the circuit layout processor 120 performs signal measurement on the circuit board produced according to the layout circuit diagram. For example, the circuit layout processor 120 may measure the signals of the first route R1, the second route R2, and the third route R3 on the circuit board manufactured by actual boarding according to the layout circuit diagram, and perform functional compatibility test.

Finally, in step S510, the circuit layout processor 120 determines whether to pass a HDMI certification specification according to a signal measurement result. To be specific, the circuit layout processor 120 may determine whether the high-speed signal on the first route R1 of the circuit board passes the HDMI 2.0 certification specification, and whether the high-speed signals on the second route R2 and the third route R3 of the circuit board pass the HDMI 2.1 certification specification according to the signal measurement result. In the case of passing the HDMI 2.0 and 2.1 certification specifications, it means that the design circuit 350 of the disclosure is successfully designed. In this way, the multiplexer in the existing design may be replaced by the design circuit 350, thereby increasing an available space on the circuit board and reducing the cost.

In summary, the circuit layout method and device in the disclosure simultaneously consider the layout design specifications of the CPU and the GPU, and select the suitable signal conditioner for matching, so as to draw the layout circuit diagram that conforms to the common board design. In this way, the multiplexer on the existing design may be replaced, thereby increasing an available space on the circuit board and reducing the cost.

What is claimed is:

1. A circuit layout method, adapted for a circuit layout of a common board circuit between a central processing unit, a graphics processing unit and a multimedia interface connector, and the common board circuit comprising a design circuit and a signal conditioner, the circuit layout method comprising:
performing a common board evaluation on a plurality of predetermined models according to a first layout design specification of the central processing unit and a second layout design specification of the graphics processing unit;
planning the design circuit according to a result of the common board evaluation;
selecting the signal conditioner that is suitable according to the planned design circuit; and
integrating the first layout design specification, the second layout design specification and a third layout design specification of the signal conditioner, and accordingly drawing a layout circuit diagram of the common board circuit.

2. The circuit layout method as recited in claim 1, wherein after drawing the layout circuit diagram of the common board circuit, the circuit layout method further comprises:
typesetting the layout circuit diagram by performing a layout placement.

3. The circuit layout method as recited in claim 2, wherein after typesetting the layout circuit diagram by performing the layout placement, the circuit layout method further comprises:
simulating a plurality of high-speed signals output by the central processing unit and the graphics processing unit according to the layout circuit diagram; and
evaluating signal quality of the high-speed signals according to a simulation result of the high-speed signals.

4. The circuit layout method as recited in claim 3, wherein after evaluating the signal quality of the high-speed signals, the circuit layout method further comprises:
performing signal measurement on a circuit board produced according to the layout circuit diagram; and
determining whether to pass a high definition multimedia interface certification specification according to a signal measurement result.

5. The circuit layout method as recited in claim 1, wherein performing the common board evaluation on the predetermined models according to the first layout design specification of the central processing unit and the second layout design specification of the graphics processing unit comprises:
determining whether planning the design circuit common to the predetermined models is feasible according to the first layout design specification and the second layout design specification.

6. The circuit layout method as recited in claim 1, wherein the design circuit comprises a first route and a second route, the first route is coupled between the central processing unit and the signal conditioner, and the second route is coupled between the graphics processing unit and the signal conditioner.

7. A circuit layout device, performing a circuit layout of a common board circuit between a central processing unit, a graphics processing unit and a multimedia interface connector, and the common board circuit comprising a design circuit and a signal conditioner, the circuit layout device comprising:
a storage device, configured to store a design rule sorting and a circuit and layout design route evaluation plan; and
a circuit layout processor, coupled to the storage device, and configured to load the design rule sorting and the circuit and layout design route evaluation plan to execute:
performing a common board evaluation on a plurality of predetermined models according to a first layout design specification of the central processing unit and a second layout design specification of the graphics processing unit;
planning the design circuit according to a result of the common board evaluation;
selecting the signal conditioner that is suitable according to the planned design circuit; and
integrating the first layout design specification, the second layout design specification and a third layout design specification of the signal conditioner, and accordingly drawing a layout circuit diagram of the common board circuit.

8. The circuit layout device as recited in claim 7, wherein the circuit layout processor typesets the layout circuit diagram by performing a layout placement.

9. The circuit layout device as recited in claim 8, wherein the circuit layout processor simulates a plurality of high-speed signals output by the central processing unit and the graphics processing unit according to the layout circuit diagram, and evaluates signal quality of the high-speed signals according to a simulation result of the high-speed signals.

10. The circuit layout device as recited in claim 9, wherein the circuit layout processor performs signal measurement on a circuit board produced according to the layout circuit diagram, and determines whether to pass a high definition multimedia interface certification specification according to a signal measurement result.

11. The circuit layout device as recited in claim 7, wherein the circuit layout processor determines whether planning the design circuit common to the predetermined models is feasible according to the first layout design specification and the second layout design specification.

12. The circuit layout device as recited in claim 7, wherein the design circuit comprises a first route and a second route, the first route is coupled between the central processing unit and the signal conditioner, and the second route is coupled between the graphics processing unit and the signal conditioner.
